(19) United States
(12) Patent Application Publication
(10) Pub. No.: US 2008/0048785 A1
(43) Pub. Date: Feb. 28, 2008

(54) Low-noise amplifier

(76) Inventors: Fuad bin Haji Mokhtar, Sungai Petami (MY); Chee Cheng Loh, Gelugor (MY)

Correspondence Address: Kathy Manke;Avago Technologies Limited, 4380 Ziegler Road, Fort Collins, CO, 80525, US

(21) Appl. No.: 11/507,857

(22) Filed: Aug. 22, 2006

(51) Int. Cl. H03F 1/22

(52) U.S. Cl. 330/311

(57) ABSTRACT

Various embodiments of a two-stage low noise amplifier (LNA) having a gain that can be adjusted without varying input its impedance are disclosed. For example, in an illustrative embodiment, an exemplary low noise amplifier can include an input stage that includes a first transistor, and an output stage that includes a second transistor. The output of the input stage can have an optional stabilizing network. The output stage is coupled to the input stage and employs a shunt-feedback configuration.

### BACKGROUND

With the constant increase in portable communications devices and overall wireless communications, the need for improved radio frequency (RF) receivers having low inherent noise increases commensurately. Unfortunately, noise in receivers is a fact of life despite the best efforts of any design engineer. There is always some background noise present in any RF receiver. The noise emanates from many sources, and although the design of the receiver should minimize noise, some will always be present. Accordingly, a concept that is very useful in many elements of signal theory, and hence in radio receiver design, is that of a receiver's “noise floor”, which can be defined as the sum of all the noise sources and unwanted signals within a system.

In order to reduce a receiver's noise floor, and thereby improve its sensitivity, it is helpful to pay close attention to the performance of any amplifier in the receiver. The appropriate use of a well-designed low noise amplifier (LNA) can ensure that the receiver's performance will be improved or maximized. Unfortunately, there are many variables of an LNA's design, such as gain, bandwidth, input impedance and power consumption, that must also be considered and yet their variance can affect the noise that the LNA inherently generates.

FIG. 1 depicts a conventional LNA 100 having a sensitivity where a change in gain will affect noise. As shown in FIG. 1, the conventional LNA 100 has a single transistor Q1 having an input coupling capacitor C1, an output coupling capacitor C2 and RF chokes L1 and L2. Resistor R1 and capacitor C3 make a shunt feedback path between the gate of transistor Q1 and the output RFout.

As the feedback capacitor C3 is a DC blocking capacitor, the feedback resistor R1 will determine the gain of the conventional LNA 100. While it may be appear to be a relatively simple task to change the LNA's gain by changing the value of the feedback resistor R1, there are several disadvantages. For example, the very introduction of the feedback resistor R1 will degrade the LNA's “noise figure”, which can be defined as the excess noise added by the LNA. Further, any change in the value of the feedback resistor R1 will also change the LNA's input impedance, and any resultant impedance mismatch can add excess noise. Thus, every change in resistor R1 may require an attendant impedance correction process by a designer in order to optimize the LNA's performance. Accordingly, it should be appreciated that new technology relating to managing an LNAs noise figure is desirable.

### SUMMARY

In an illustrative embodiment, a low noise amplifier (LNA) having a gain that can be adjusted without varying input impedance includes an input stage that includes a first transistor where the output of the first transistor is connecting to a stabilizing network consists of a resistor in series with a capacitor, and an output stage that includes a second transistor, the output stage being coupled to the input stage, wherein the output stage has a shunt-feedback configuration.

In another embodiment, a low noise amplifier (LNA) having a gain that can be adjusted without varying input impedance includes an input stage that includes a first transistor, wherein the input stage is configured as a common source amplifier, and an output stage that includes a second transistor configured as a common gate amplifier, the output stage being coupled to the input stage.

In yet another embodiment, a low noise amplifier (LNA) having a gain that can be adjusted without varying input impedance includes an input stage that includes a first transistor, wherein the input stage is configured as a common emitter amplifier, and an output stage that includes a second transistor configured as a common base amplifier, the output stage being coupled to the input stage.

### DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a conventional low noise amplifier; and

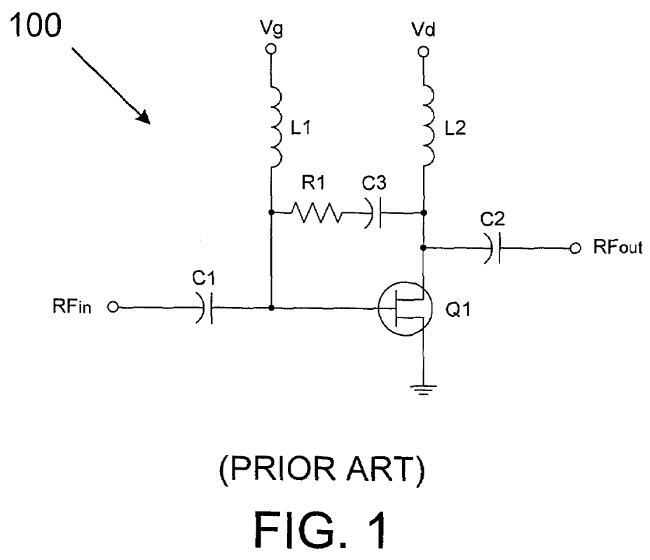

FIG. 2 is an improved low noise amplifier having a gain that can be adjusted without changing its input impedance.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are clearly within the scope of the present teachings.

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

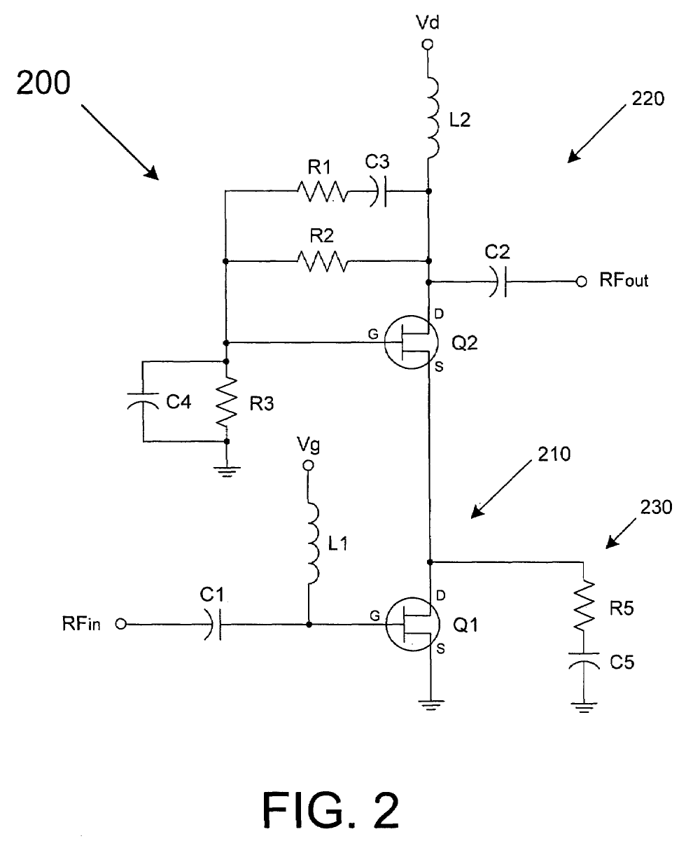

FIG. 2 is an improved low noise amplifier 200 having a gain that can be adjusted without changing its input impedance. As shown in FIG. 2, the low noise amplifier 200 includes an input stage 210 having transistor Q1 and an output stage 220 having transistor Q2.

The exemplary transistors Q1 and Q2 are N-channel field-effect transistors (FETs), and in various embodiments can take the form of JFET or MOSFET transistors. As may be appreciated by those skilled in the art, the first transistor Q1 has a common source configuration and the second transistor Q2 has a common gate configuration. The second transistor Q2 also has a “shunt-feedback” network of resistor R1 and capacitor C3, which are arranged in series and coupled between the drain and the gate of transistor Q2.

The biasing of transistor Q1 is achieved using blocking inductor L1, which is tied between the gate of transistor Q1 and a biasing voltage Vg of the low noise amplifier 200. Biasing of transistor Q2 is provided by resistors R2 and R3, which acts as a voltage divider between the power supply voltage Vd and ground/common. Note, however, that in various embodiments it may be preferable to use other voltage sources to provide biasing for one or both of transistor Q1 and Q2.

In the illustrative embodiment of FIG. 2, the drain/output of the first transistor Q1 is optionally coupled to a optional stabilizing network 230, which in the present embodiment consists of a resistor R5 in series with a capacitor C5, connected between the drain/output of Q1 and ground. However, it should be appreciated that other network configurations may be used to provide stabilization in other embodiments.

In operation, an input signal, typically an RF signal between 1 GHz and 5 Ghz, can be presented to input node RFin allowing capacitor C1 to couple the input signal to the first transistor Q1. In response, the first transistor Q1 can produce a first amplified version of the input signal at its drain/output.

In response to the first amplified signal, the second transistor Q2, whose source is coupled (directly or via an optional electrical network) to the drain of Q1, can produce a second amplified signal at its drain, which can then be coupled by capacitor C2 to output node RFout.

Note that the drain of the second transistor Q2 can be isolated from supply voltage Vd by inductor L2.

By first setting resistors R2 and R3 to establish the gate bias of transistor Q2, the gain of the output stage 220 can be freely set by simply varying the value of resistor R1, which will not affect the biasing of transistor Q2 by virtue of blocking capacitor C3. A capacitor C4 optionally can be placed in parallel with resistor R3 to further improve performance.

The advantages of the low noise amplifier 200 of FIG. 2 include that overall gain can be varied by a simple adjustment of resistor R1, which will have no appreciable affect on the input impedance at the input node RFin. That is, due to the isolation between the amplifier's input and output stages 210 and 220, there is no design tradeoff between the introduction and variance of the shunt-feedback network (R1 and C3) of transistor Q2 and noise introduced by a potential impedance mismatch that might otherwise occur at the gate of Q1. Noise levels of transistor Q2 can thus be generally limited to thermal noise generated by resistors R1-R3.

While noise may also be introduced to the low noise amplifier 200 as a function of the biasing and size of transistors Q1 and Q2, as well as the nature (e.g., material used and thickness) of the bond wires used in strategic locations (such as at the source of transistor Q1), these issues are controllable, and thus further reductions in a low noise amplifier's noise factor may need careful attention to these design details.

While in the example above the transistors Q1 and Q2 are FET transistors, it should be appreciated that, in varying embodiments, n-p-n bipolar transistors may be used without substantial deviation from the general layout of FIG. 2. However, there may be some differences to procure optimum performance. For example, the biasing circuitry of transistor Q1 (inductor L1) may be complemented by a resistive voltage divider, and the first capacitor C1 may be replaced by a capacitor in series with yet another resistor. Additionally, for transistor Q2, the values of resistors R2 and R3 may change, or in some embodiments R2 may be eliminated or perhaps tied between the base and the power supply voltage Vd via a choke.

In still other embodiments it may be desirable to mix bipolar and FET transistors such that Q1 or Q2 is a bipolar device while the other transistor Q2 or Q1 is a FET device.

In still yet other embodiments, the general approach employed with the low noise amplifier 200 of FIG. 2 can be altered to use P-channel FETs or p-n-p bipolar transistors. Such alterations Would naturally take into account the use of different power supply voltages, but overall topography and biasing schemes may remain consistent.

The many features and advantages of the disclosed methods and systems are apparent from the detailed specification, and thus, it is intended by the appended claims to cover all such features and advantages that fall within their true spirit and scope. Further, since numerous modifications and variations will readily occur to those skilled in the art, it is not desired to limit the scope of the disclosure to the exact construction and operation illustrated and described, and accordingly, all suitable modifications and equivalents may be resorted to, falling within the scope of the disclosed methods and systems.

1. A low noise amplifier (LNA) having a gain that can be adjusted without varying its input impedance, comprising:
an input stage that includes a first transistor; and
an output stage that includes a second transistor, the output stage being coupled to the input stage, wherein the output stage is configured to have a shunt-feedback network.

2. The low noise amplifier of claim 1, wherein the input stage includes an input node coupled to the gate of the first transistor using a first capacitor, and wherein the gate of the first transistor is biased via a first blocking inductor tied to a non-ground voltage.

3. The low noise amplifier of claim 2, wherein the non-ground voltage is a power supply voltage of the low noise amplifier.

4. The low noise amplifier of claim 2, wherein at least one of the size of the first transistor, the bias the first transistor and the nature of at least one bond wire of the first transistor is substantially optimized to reduce the noise figure of the input stage.

5. The low noise amplifier of claim 1, wherein the first and second transistors are FET transistors, and the drain of the first transistor is electrically coupled to the source of the second transistor.

6. The low noise amplifier of claim 5, wherein the drain of the first transistor is directly coupled to the source of the second transistor.

7. The low noise amplifier of claim 5, the input stage has a common source configuration.

8. The low noise amplifier of claim 5, the output stage has a common gate configuration.

9. The low noise amplifier of claim 1, wherein the output of the first transistor is coupled to a stabilizing network.

10. The low noise amplifier of claim 9, wherein stabilizing network includes a resistor in series with a capacitor.

11. The low noise amplifier of claim 1, wherein the shunt-feedback network consists of a resistor in series with a capacitor.

12. The low noise amplifier of claim 8, wherein the output stage further includes a second inductor tied between the drain of the second transistor and the power supply of the low noise amplifier.

13. The low noise amplifier of claim 8, wherein the output stage further includes a second resistor tied between the drain and gate of the second transistor and a third resistor tied between ground and the gate of the second transistor.

14. A low noise amplifier (LNA) having a gain that can be adjusted without varying its input impedance, comprising:
an input stage that includes a first transistor, wherein the input stage is configured as a common emitter amplifier; and
an output stage that includes a second transistor, the output stage being coupled to the input stage and configured to have a shunt-feedback network between its base and collector.

15. The low noise amplifier of claim 14, wherein the output stage is configured as a common base amplifier.

16. The low noise amplifier of claim 14, wherein the shunt-feedback network consists of a resistor in series with a capacitor.

17. A low noise amplifier (LNA) having a gain that can be adjusted without varying input impedance, comprising:
an input stage that includes a first transistor, wherein the input stage is configured as a common emitter amplifier; and
an output stage that includes a second transistor configured as a common base amplifier, the output stage being coupled to the input stage.

18. The low noise amplifier of claim 17, wherein the collector of the first transistor is directly coupled to the emitter of the second transistor.

19. The low noise amplifier of claim 17, wherein the output stage is further configured to have a shunt-feedback network consisting of a resistor in series with a capacitor tied between the collector and base of the second transistor.

20. The low noise amplifier of claim 17, wherein the input stage is further configured to have a stabilizing network consisting of a resistor in series with a capacitor tied between the collector of the first transistor to ground.
